(19) United States
(12) Patent Application Publication
(10) Pub. No.: US 2024/0230966 A1
(43) Pub. Date: Jul. 11, 2024

(54) DISPLAY DEVICE

(71) Applicants: Fuzhou BOE Optoelectronics Technology Co., Ltd., Fuzhou (CN); BOE Technology Group Co., Ltd., Beijing (CN)

(72) Inventors: Tao FANG, Beijing (CN); Baoqiang WANG, Beijing (CN); Tianfeng ZHANG, Beijing (CN); Zecun ZENG, Beijing (CN); Wenli FAN, Beijing (CN)

(21) Appl. No.: 18/616,552

(22) Filed: Mar. 26, 2024

Related U.S. Application Data
(63) Continuation of application No. PCT/CN2021/142652, filed on Dec. 29, 2021.

(51) Int. Cl. G02B 5/02; H01L 27/12

(52) U.S. Cl. CPC G02B 5/0294; G02B 5/0242; H01L 27/124

(57) ABSTRACT

The present disclosure provides a display device. The display device comprises: a display panel, comprising a plurality of sub-pixels arranged in an array, the colors of any two adjacent sub-pixels being different; and a moiré suppression layer, located on the light emitting side of the display panel.

### CROSS REFERENCE TO RELATED APPLICATIONS

This application is continuation application of International Application No. CT/CN2021/142652, filed on Dec. 29, 2021, the entire content of which is incorporated herein by reference.

### TECHNICAL FIELD

The disclosure relates to the field of a display technology, in particular to a display device.

### BACKGROUND

With the continuous development of display technology, three-dimensional (3D) display technology has attracted more and more attention. Three-dimensional display technology enables the display image to be three-dimensional and realistic. The principle of the 3D display technology is as follows: the left and right eyes of a person receive a left-eye image and a right-eye image with a certain parallax respectively, when the two images with parallax are respectively received by the left and right eyes of the person, the image information is superimposed and fused by the brain to form a 3D visual display.

However, in the related art, the image of 3D display products has severe moiré, which affects the display effect.

### SUMMARY

Embodiments of the disclosure provide a display device, and the display device includes: a display panel including a plurality of sub-pixels arranged in an array, where any two adjacent sub-pixels have different colors; and a moiré suppression layer located at a light emitting side of the display panel.

In some embodiments, the moiré suppression layer includes: a light scattering film.

In some embodiments, the display device further includes: a polarizer disposed at the light-emitting side of the display panel; and a lens structure disposed at a side of the light scattering film facing away from the display panel and including a plurality of lenses arranged in an array. The light scattering film is disposed between the polarizer and the lens structure, or the light scattering film is disposed at a side of the lens structure facing away from the polarizer.

In some embodiments, the moiré suppression layer further includes: a haze layer inside the polarizer.

In some embodiments, the moiré suppression layer includes: a haze layer.

In some embodiments, the display device further includes: a polarizer disposed at the light-emitting side of the display panel, where the haze layer is disposed inside the polarizer; and a lens structure disposed at a side of the polarizer facing away from the display panel and including a plurality of lenses arranged in an array.

In some embodiments, the polarizer includes a first protective layer, a polarizing layer, and a second protective layer stacked at the light-emitting side of the display panel. The haze layer is at least positioned as one of following: the haze layer is disposed at a side of the second protective layer facing the lens structure, the haze layer is disposed between the second protective layer and the polarizing layer, the haze layer is disposed between the first protective layer and the polarizing layer, or the haze layer is disposed at a side of the first protective layer facing the display panel.

In some embodiments, the haze layer includes: an adhesive material, and dispersion particles dispersed at least in the adhesive material.

In some embodiments, a material of the dispersion particles includes silicon.

In some embodiments, the polarizer further includes: an anti-glare low-reflection layer.

The anti-glare low-reflection layer is disposed at a side of the second protective layer facing the light scattering film. Or, the second protective layer is reused as the anti-glare low-reflection layer.

In some embodiments, the anti-glare low-reflection layer has a haze greater than zero.

In some embodiments, the haze layer includes: a first sub-haze layer and a second sub-haze layer arranged in stack.

In some embodiments, a haze of the haze layer is greater than or equal to 25%.

In some embodiments, the display panel includes: a first base substrate; a plurality of scanning lines disposed at a side of the first base substrate facing the moiré suppression layer and extending along a first direction and arranged along a second direction, where the first direction intersects with the second direction; and a plurality of first signal lines dispose at the side of the first base substrate facing the moiré suppression layer and arranged along the first direction. A shape of the orthographic projection of the first signal line on the first base substrate is a folded line shape.

In some embodiments, the first signal line includes: a plurality of first parts extending along a third direction, a plurality of second parts extending along a fourth direction, and third parts extending along the second direction. The first part, the second part and the third part are sequentially connected, the third direction intersects with the fourth direction, and the third direction and the fourth direction both intersect with the second direction.

In some embodiments, an orthographic projection of the first part on the first base substrate and an orthographic projection of the second part on the first base substrate both overlap with an orthographic projection of a sub-pixel on the first base substrate; and an orthographic projection of the third part on the first base substrate does not overlap with the orthographic projection of the sub-pixel on the first base substrate.

In some embodiments, the display panel further includes: a plurality of pixel electrodes corresponding to the sub-pixels in a one-to-one manner. The plurality of pixel electrodes include: a first sub-electrode, a second sub-electrode, and a connection line between the first sub-electrode and the second sub-electrode for connecting the first sub-electrode and the second sub-electrode. In the first direction, an orthographic projection of the first sub-electrode on the first base substrate and an orthographic projection of the second sub-electrode on the first base substrate are respectively located at both sides of an orthographic projection of the first signal line on the first base substrate, and an orthographic projection of the connection line on the first base substrate overlaps with an orthographic projection of a connection of the first part and the second part on the first base substrate.

In some embodiments, the first signal line includes: a plurality of first parts extending along a third direction, a plurality of second parts extending along the first direction, and third parts extending along the second direction. The first part, the second part, and the third part are sequentially connected, and the third direction intersects with the first direction and the second direction.

In some embodiments, an orthographic projection of the first part on the first base substrate and an orthographic projection of the second part on the first base substrate both overlap with an orthographic projection of a sub-pixel on the first base substrate; and an orthographic projection of the third part on the first base substrate does not overlap with the orthographic projection of the sub-pixel on the first base substrate.

In some embodiments, the display panel further includes: a plurality of pixel electrodes corresponding to the sub-pixels in a one-to-one manner. The pixel electrode is a block electrode.

The orthographic projection of the first part on the first base substrate and the orthographic projection of the second part on the first base substrate both overlap with an orthographic projection of a pixel electrode on the first base substrate.

In some embodiments, the display panel further includes a common electrode. The common electrode includes at least one slit located in the sub-pixel and passing through the common electrode along a thickness direction of the common electrode. The slit is parallel to the first signal line.

In some embodiments, the display panel further includes a common electrode. The common electrode includes a slit passing through the common electrode along a thickness direction of the common electrode. The slit extends along the second direction. An orthographic projection of the slit on the first base substrate overlaps with a region between adjacent sub-pixels.

In some embodiments, the plurality of first signal lines include: a plurality of data lines and a plurality of common electrode lines which are arranged alternately.

### BRIEF DESCRIPTION OF FIGURES

In order to illustrate technical solutions of embodiments of the disclosure more clearly, drawings that need to be used in the description of the embodiments will be briefly introduced below. Obviously, the drawings in the following description are only some embodiments of the disclosure, and those ordinary skilled in the art may further obtain other drawings based on these drawings without making creative efforts.

FIG. 1 is a schematic structural diagram of a display device provided by embodiments of the disclosure.

FIG. 2 is a schematic diagram of an arrangement of sub-pixels in a display device provided by embodiments of the disclosure.

FIG. 3 is another schematic structural diagram of a display device provided by embodiments of the disclosure.

FIG. 4 is another schematic structural diagram of a display device provided by embodiments of the disclosure.

FIG. 5 is another schematic structural diagram of a display device provided by embodiments of the disclosure.

FIG. 6 is another schematic structural diagram of a display device provided by embodiments of the disclosure.

FIG. 7 is another schematic structural diagram of a display device provided by embodiments of the disclosure.

FIG. 8 is another schematic structural diagram of a display device provided by embodiments of the disclosure.

FIG. 9 is another schematic structural diagram of a display device provided by embodiments of the disclosure.

FIG. 10 is another schematic structural diagram of a display device provided by embodiments of the disclosure.

FIG. 11 is another schematic structural diagram of a display device provided by embodiments of the disclosure.

FIG. 12 is another schematic structural diagram of a display device provided by embodiments of the disclosure.

FIG. 13 is another schematic structural diagram of a display device provided by embodiments of the disclosure.

FIG. 14 is another schematic structural diagram of a display device provided by embodiments of the disclosure.

FIG. 15 is another schematic structural diagram of a display device provided by embodiments of the disclosure.

FIG. 16 is another schematic structural diagram of a display device provided by embodiments of the disclosure.

FIG. 17 is another schematic structural diagram of a display device provided by embodiments of the disclosure.

FIG. 18 is a schematic structural diagram of a display panel in a display device provided by embodiments of the disclosure.

FIG. 19 is another schematic structural diagram of a display panel in a display device provided by embodiments of the disclosure.

FIG. 20 is another schematic structural diagram of a display panel in a display device provided by embodiments of the disclosure.

FIG. 21 is another schematic structural diagram of a display panel in a display device provided by embodiments of the disclosure.

FIG. 22 is another schematic structural diagram of a display panel in a display device provided by embodiments of the disclosure.

FIG. 23 is another schematic structural diagram of a display panel in a display device provided by embodiments of the disclosure.

FIG. 24 is another schematic structural diagram of a display panel in a display device provided by embodiments of the disclosure.

### DETAILED DESCRIPTION

In order to make the purpose, technical solutions and advantages of the embodiments of the disclosure clearer, the technical solutions of the embodiments of the disclosure will be clearly and completely described below in conjunction with drawings of the embodiments of the disclosure. Apparently, in the case of no conflict, the described embodiments are some embodiments but not all embodiments of the disclosure. Moreover, the embodiments in the disclosure and features in the embodiments may be mutually combined without conflicts. Based on the described embodiments of the disclosure, all other embodiments obtained by those ordinarily skilled in the art without creative work fall within the protection scope of the disclosure.

Unless otherwise defined, technical or scientific terms used in the disclosure shall have the ordinary meanings as understood by those with ordinary skills in the art to which the disclosure belongs. Words “first”, “second” and similar words used in the disclosure do not indicate any order, quantity or importance, but are only used to distinguish different components. Word “comprise” or “include” or other similar words mean that the element or item appearing before the word encompasses the element or item listed after the word and its equivalents, but does not exclude other elements or items. Word “connecting” or “connected” or similar words are not limited to physical or mechanical connections, but may include electrical connections, whether direct or indirect.

It should be noted that that the size and shape of each figure in the drawings do not reflect the true scale, but are only intended to illustrate the content of the disclosure. And the same or similar reference numerals indicate the same or similar elements or elements having the same or similar functions throughout.

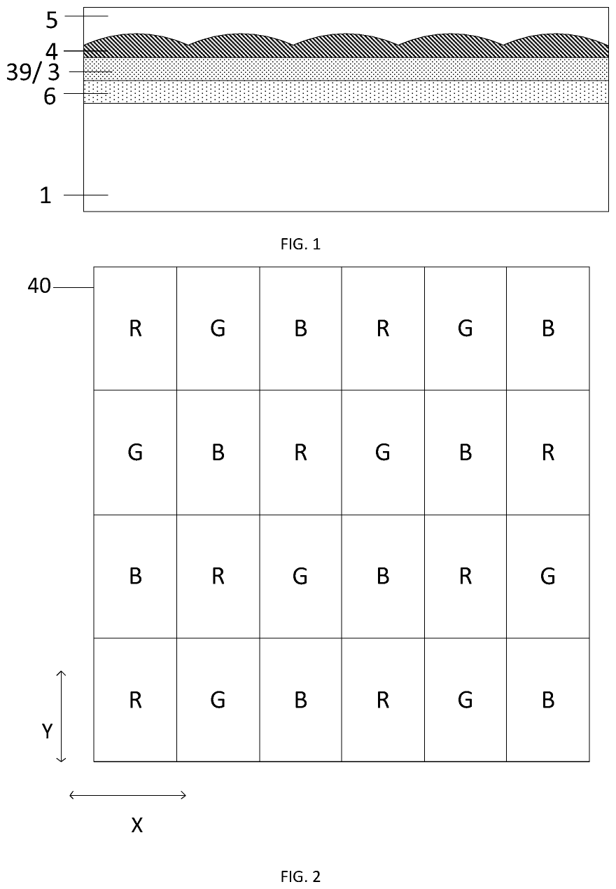

Embodiments of the disclosure provide a display device, as shown in FIG. 1, the display device includes:
a display panel 1, as shown in FIG. 2, including a plurality of sub-pixels 40 arranged in an array; where colors of any two adjacent sub-pixels 40 are different;
a moiré suppression layer 39 disposed at a light emitting side of the display panel 1.

In the display device provided by the embodiments of the disclosure, a moiré suppression layer is provided at the light-emitting side of the display panel. The moiré suppression layer can alleviate the moiré of the display device and improve the display effect.

In some embodiments, as shown in FIG. 2, the plurality of sub-pixels 40 include: a red sub-pixel R, a green sub-pixel G, and a blue sub-pixel B, and the plurality of sub-pixels are arranged along a first direction X and a second direction Y. The colors of any two adjacent sub-pixels 40 in the first direction X are different, and the colors of any two adjacent sub-pixels 40 in the second direction Y are also different. In FIG. 2, the first direction X is perpendicular to the second direction Y.

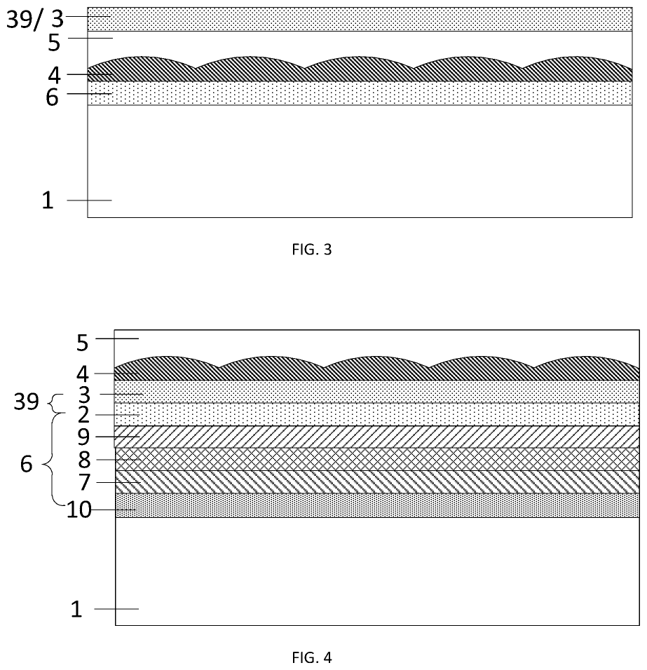

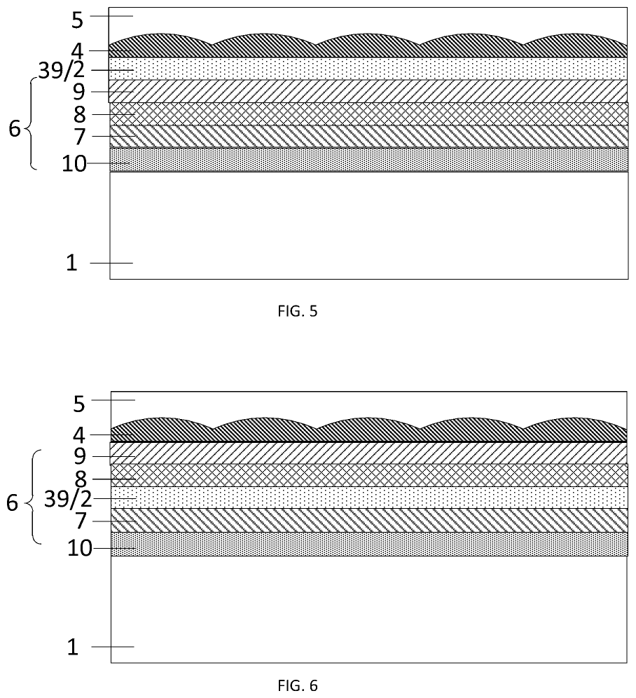

In some embodiments, as shown in FIG. 1, FIG. 3, FIG. 4, and FIG. 5, the display device further includes:
a polarizer 6, disposed at the light emitting side of the display panel 1; and
a lens structure 4, located at a side of the polarizer 6 facing away from the display panel 1, and including a plurality of lenses arranged in an array.

In some embodiments, the lens is a lenticular lens.

In some embodiments, the light of the sub-pixel in the display device is refracted by the lenticular lens, and the images with parallax are projected to the left and right eyes of the user, and the stereoscopic effect is obtained through the three-dimensional fusion of the visual center, thereby realizing 3D display.

In some embodiments, as shown in FIG. 1, FIG. 3, and FIG. 4, the moiré suppression layer 39 includes: a light scattering film 3.

It should be noted that the light scattering film a one-dimensional or two-dimensional polymer microstructure formed by curing via ultraviolet light, so that it can scatter incident light in a certain direction and enhance the reflectivity in the certain direction.

In the display device provided by the embodiments of the disclosure, since the moiré suppression layer includes the light scattering film, the light scattering film can scatter the incident light in a certain direction, so that when the light passes through the light scattering film, the degree the scattering of the light can be changed, and thus asymmetric scattering is formed within the visual range, to reduce the moiré effect and improve the display effect.

In some embodiments, as shown in FIG. 1 and FIG. 4, the light scattering film 3 is disposed between the polarizer 6 and the lens structure 4.

In the display device provided by the embodiments of the disclosure, the light scattering film is disposed between the polarizer and the lens structure, so that after passing through the light scattering film, the degree of scattering of the light emitted from the sub-pixels of the display panel can be changed, to form an asymmetric scattering effect in the visual range; and after the passing through the lenticular lens, the interference due to the sub-pixel size and the lenticular lens is weakened, so that the moiré can be further suppressed, and the display effect can be further improved.

Alternatively, in some embodiments, as shown in FIG. 3, the light scattering film 3 is disposed at a side of the lens structure 4 facing away from the polarizer 6.

In some embodiments, as shown in FIG. 1, FIG. 3, FIG. 4, and FIG. 5, the display device further includes a planarization layer 5.

In some embodiments, as shown in FIG. 4, the moiré suppression layer 39 further includes: a haze layer 2.

In the display device provided by the embodiments of the disclosure, the moiré suppression layer further includes the haze layer, which can change the propagation direction of the light passing through the haze layer, after the light emitted from the display panel passes through the haze layer, part of the light can be dispersed to other viewing angles, and the regular reflection may be suppressed, so that the moiré of the display device can be further alleviated, and the display effect can be further improved.

In some embodiments, when the moiré suppression layer includes the haze layer 2 and the light scattering film 3, the light scattering film 3 is disposed at a side of the haze layer 2 facing away from the display panel 1.

In some embodiments, as shown in FIG. 4, the haze layer 2 is located inside the polarizer.

In some embodiments, as shown in FIG. 5, the moiré suppression layer 39 includes: a haze layer 2. In this case, the moiré suppressing layer only includes the haze layer.

In the display device provided by the embodiments of the disclosure, the moiré suppression layer includes the haze layer, which can change the propagation direction of light passing through the haze layer. After the light emitted from the display panel passes through the haze layer, part of the light can be dispersed to other viewing angles, the regular reflection may be suppressed, to alleviate the moiré of the display device and improve the display effect.

In some embodiments, as shown in FIG. 5, the haze layer 2 is located inside the polarizer 6.

It should be noted that, as shown in FIG. 4 and FIG. 5, when the moiré suppression layer 39 includes the haze layer 2, the haze layer 2 is located inside the polarizer 6. That is, in the display device provided by the embodiments of the disclosure, the polarizer is a haze polarizer.

Examples of the haze layer being located inside the polarizer are described below.

In some embodiments, as shown in FIGS. 4 to 15, the polarizer 6 includes a first protective layer 7, a polarizing layer 8, and a second protective layer 9 stacked at the light-emitting side of the display panel 1; and
the haze layer 2 is positioned as at least one of following:
the haze layer is disposed on a side of the second protective layer 9 facing the lens structure 4, the haze layer is disposed between the second protective layer 9 and the polarizing layer 8, the haze layer is disposed between the first protective layer 7 and the polarizing layer 8, or the haze layer is disposed on a side of the first protective layer 7 facing the display panel 1.

In some embodiments, when the polarizer includes one haze layer, the specific position of the haze layer is set as follows.

In some embodiments, as shown in FIG. 4 and FIG. 5, the haze layer 2 is disposed on a side of the second protective layer 9 away from the polarizing layer 8.

Alternatively, in some embodiments, as shown in FIG. 6, the haze layer 2 is disposed between the first protective layer 7 and the polarizing layer 8.

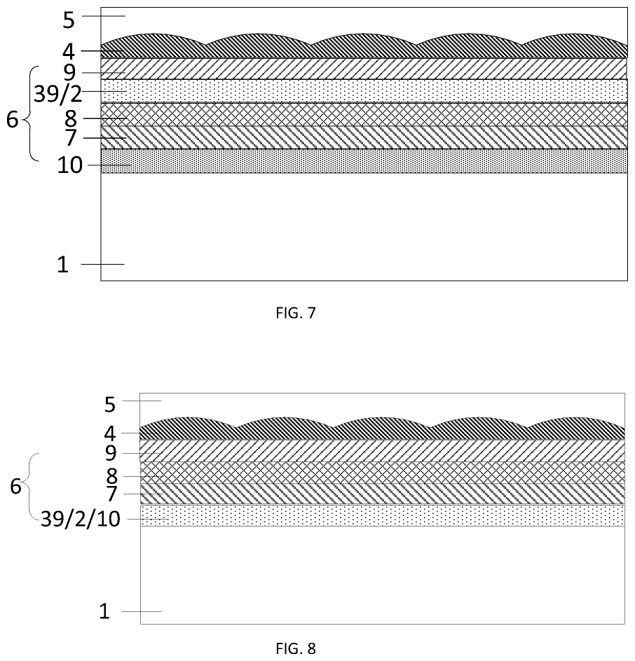

Alternatively, in some embodiments, as shown in FIG. 7, the haze layer 2 is disposed between the second protective layer 9 and the polarizing layer 8.

Alternatively, in some embodiments, as shown in FIG. 8, the haze layer 2 is disposed on a side of the first protective layer 7 away from the polarizing layer 8.

It should be noted that, an example in which the moiré suppression layer includes a haze layer and a light scattering layer is illustrated in FIG. 4, and an example in which the moiré suppression layer includes only a haze layer is illustrated in FIGS. 5 to 8. In some embodiments, when the moiré suppression layer further includes the light scattering film, the light scattering film may be provided between the polarizer and the lens structure or on a side of the lens structure facing away from the polarizer in FIGS. 6 to 8.

Of course, in some embodiments, the polarizer may also include multiple haze layers to further improve moiré.

In some embodiments, the polarizer may include two haze layers. When the polarizer includes two haze layers, the specific positions of the haze layers are set as follows.

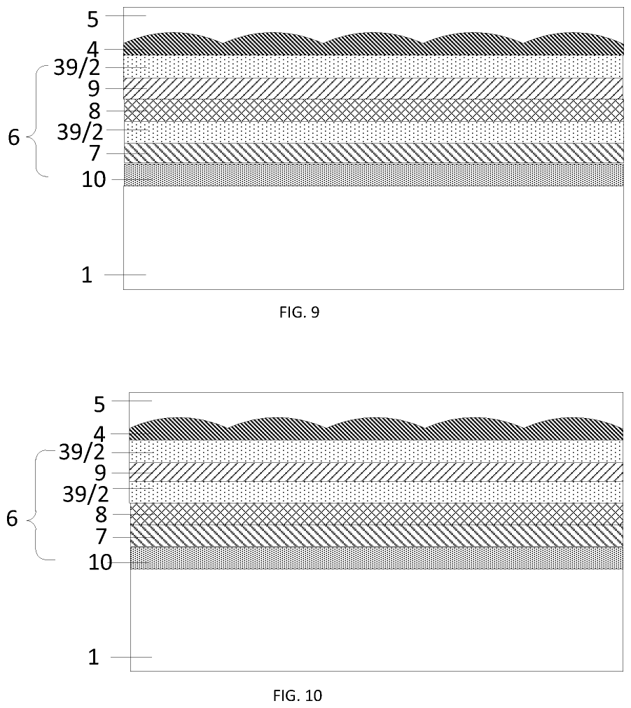

In some embodiments, as shown in FIG. 9, the haze layer 2 is disposed on the side of the second protective layer 9 away from the polarizing layer 8, and further disposed between the first protective layer 7 and the polarizing layer 8.

Alternatively, in some embodiments, as shown in FIG. 10, the haze layer 2 is disposed on the side of the second protective layer 9 away from the polarizing layer 8, and further disposed between the second protective layer 9 and the polarizing layer 8.

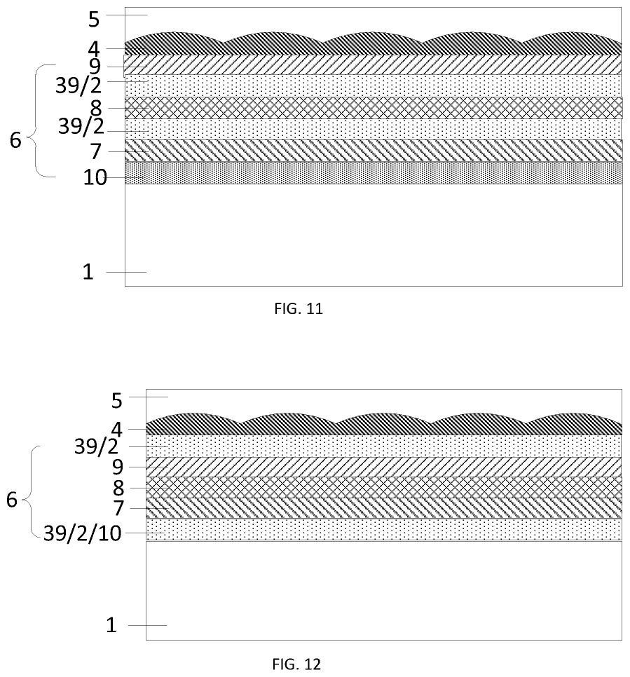

Alternatively, in some embodiments, as shown in FIG. 11, the haze layer 2 is disposed between the second protective layer 9 and the polarizing layer 8, and further disposed between the first protective layer 7 and the polarizing layer 8.

Alternatively, in some embodiments, as shown in FIG. 12, the haze layer 2 is disposed on the side of the second protective layer 9 away from the polarizing layer 8, and further disposed on the side of the first protective layer 7 away from the polarizing layer 8.

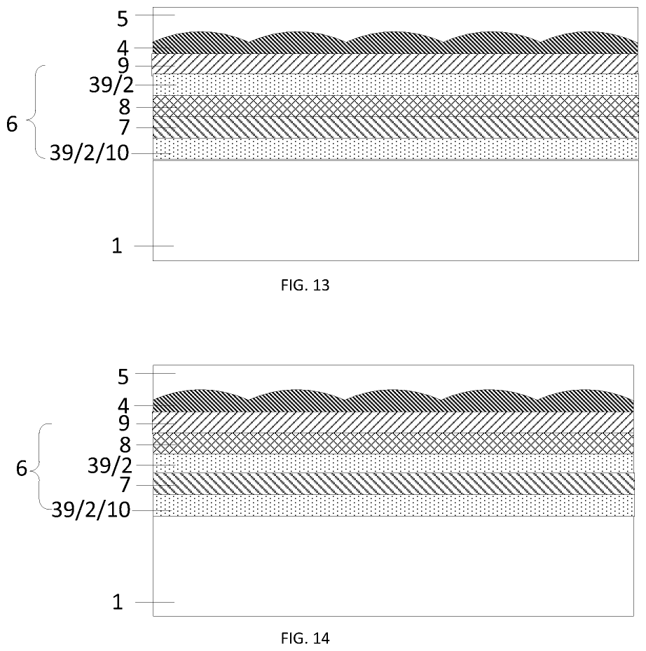

Alternatively, in some embodiments, as shown in FIG. 13, the haze layer 2 is disposed between the second protective layer 9 and the polarizing layer 8, and further disposed on the side of the first protective layer 7 away from the polarizing layer 8.

Alternatively, in some embodiments, as shown in FIG. 14, the haze layer 2 is disposed between the first protective layer 7 and the polarizing layer 8, and further dispose on the side of the first protective layer 7 away from the polarizing layer 8.

It should be noted that, in FIGS. 9 to 14, the moiré suppression layer includes only the haze layers as an example for illustration. In some embodiments, when the moiré suppression layer further includes the light scattering film, the light scattering film may be provided between the polarizer and the lens structure or on the side of the lens structure facing away from the polarizer in FIGS. 9 to 14.

Of course, in some embodiments, the polarizer may also include three or four haze layers.

In some embodiments, when the polarizer includes multiple haze layers, the moiré of the display device can be further improved.

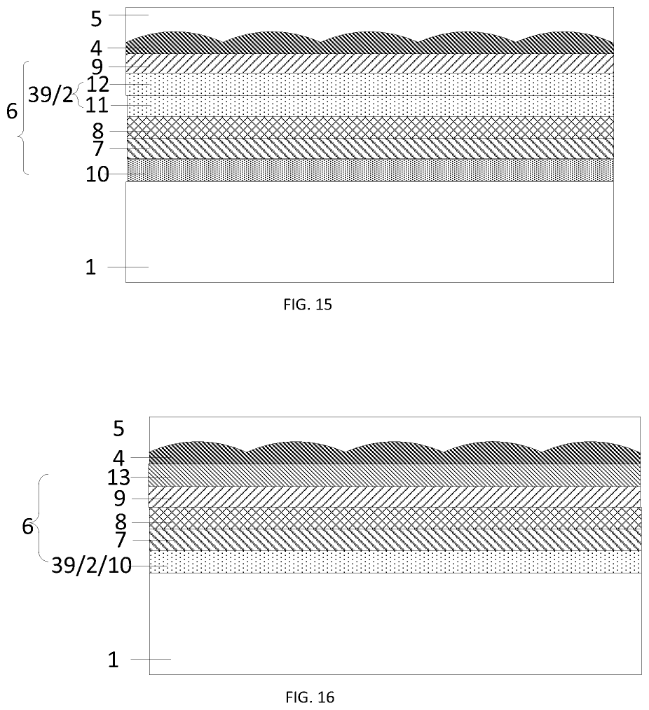

Certainly, in some embodiments, as shown in FIG. 15, the haze layer includes: a first sub-haze layer 11 and a second sub-haze layer 12 which are stacked.

That is, two layers of haze layers are stacked.

The haze layer includes a first sub-haze layer and a second sub-haze layer that are stacked, so that the moiré of the display device can be further improved.

It should be noted that in FIG. 15, the first sub-haze layer 11 and the second sub-haze layer 12 being stacked between the first protective layer 7 and the polarizing layer 8, and the moiré suppression layer only including the haze layer are illustrated as an example. In some embodiments, any single haze layer in FIG. 4 to FIG. 14 can be replaced by two stacked sub-haze layers. In some embodiments, when the moiré suppression layer further includes the light scattering film, the light scattering film may be provided between the polarizer and the lens structure or on the side of the lens structure facing away from the polarizer in FIG. 15.

In some embodiments, the first sub-haze layer and the second sub-haze layer may be the same or different.

In some embodiments, the haze of the haze layer is greater than or equal to 25%. For example, the haze of the haze layer is 55%, 65%, and the like. That is, the embodiments of the disclosure may use a haze layer with a relatively high haze, which is more conducive to improving moiré and improving display effect.

In some embodiments, the higher the haze of the haze layer, the better the moiré improvement and the better the display effect. For example, the moiré improvement effect of the display device when the haze of the haze layer is 65% is better than the moiré improvement effect of the display device when the haze is 55%. During specific implementation, an appropriate haze can be selected according to actual conditions such as cost and process.

In some embodiments, the haze layer includes an adhesive material; and dispersion particles dispersed at least in the adhesive material.

In the display device provided by the embodiments of the disclosure, the haze layer includes adhesive material and dispersion particles, so that the haze layer may play the role of adhering to the adjacent film layer while dispersing the propagation direction of light. There is no need to provide additional adhesive materials to attach the haze layer to the adjacent film layer, which can further simplify the structure of the display device and save costs.

In some embodiments, as shown in FIGS. 4 to 15, the polarizer 6 further includes an adhesive material 10 disposed on the side of the first protective layer 7 facing the display panel 1 and bonded to the display panel 1. When the haze layer 2 is disposed on the side of the first protective layer 7 facing the display panel 1, the adhesive material 10 bonded to the display panel 1 is reused as the haze layer 2.

In some embodiments, the adhesive material is pressure sensitive adhesive.

In some embodiments, the material of the dispersion particles includes silicon.

That is, silicon particles can be added to the pressure sensitive adhesive.

In some embodiments, the polarizer further includes: an anti-glare low-reflection (AGLR) layer.

In some embodiments, the anti-glare low-reflection layer is a low-reflection layer, which can reduce the light reflection to improve the light utilization rate of the display device.

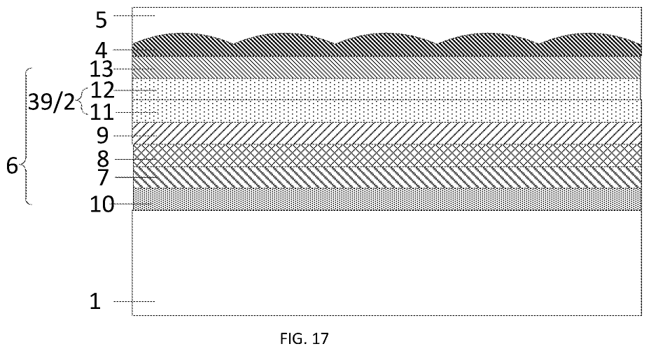

In some embodiments, as shown in FIG. 16 and FIG. 17, there is an anti-glare low-reflection layer 13 at a side of the second protective layer 9 facing the light scattering film 3.

In FIG. 16, the haze layer 2 being disposed between the first protective layer 8 and the display panel 1 for illustration is illustrated for example. In FIG. 17, the haze layer 2 including a first sub-haze layer 11 and a second sub-haze layer 12 which are stacked, and the haze layer 2 being disposed between the second protective layer 9 and the AGLR layer 13 are illustrated for example.

Alternatively, in some embodiments, the second protection layer is reused as AGLR layer.

In some embodiments, the AGLR layer has a haze greater than zero. That is, the AGLR layer is a film layer with haze. The AGLR layer may undergo a haze treatment. For example, the AGLR layer has a haze of 1%.

It should be noted that, in FIGS. 16 and 17, the moiré suppression layer only includes the haze layer as an example for illustration. In some embodiments, when the moiré suppression layer further includes the light scattering film, the light scattering film may be provided between the polarizer and the lens structure or on a side of the lens structure facing away from the polarizer in FIGS. 16 to 17.

In some embodiments, the materials of the first protective layer and the second protective layer include one or a combination of the following: polyethylene terephthalate (PET), acrylic, cyclo olefin polymer (COP), and triacetyl cellulose (TAC). In some embodiments, TAC may be, for example, no retardation tac (NRT). In some embodiments, the material of the polarizing layer includes: polyvinyl alcohol (PVA). PET is one of resins.

In some embodiments, the materials of the first protective layer and the second protective layer may be the same or different.

In some embodiments, a thickness of the haze layer is greater than or equal to 15 microns and less than or equal to 60 microns. In some embodiments, when the haze layer is a single layer, for example, the haze layer is 18 microns. In some embodiments, when the haze layer includes the first sub-haze layer and the second sub-haze layer, the thicknesses of the first sub-haze layer and the second sub-haze layer may be the same, for example, 25 microns. Certainly, the thicknesses of the first sub-haze layer and the second sub-haze layer may also be different.

In some embodiments, a thickness of the first protective layer is, for example, 40 microns; a thickness of the polarizing layer is about 20 microns to 22 microns. A thickness of the second protective layer is about 60 microns to 90 microns. When the second protective layer is reused as the AGLR layer, the thickness of the second protective layer is, for example, 84 microns. When the AGLR is additionally provided, the thickness of the AGLR layer is, for example, 45 microns.

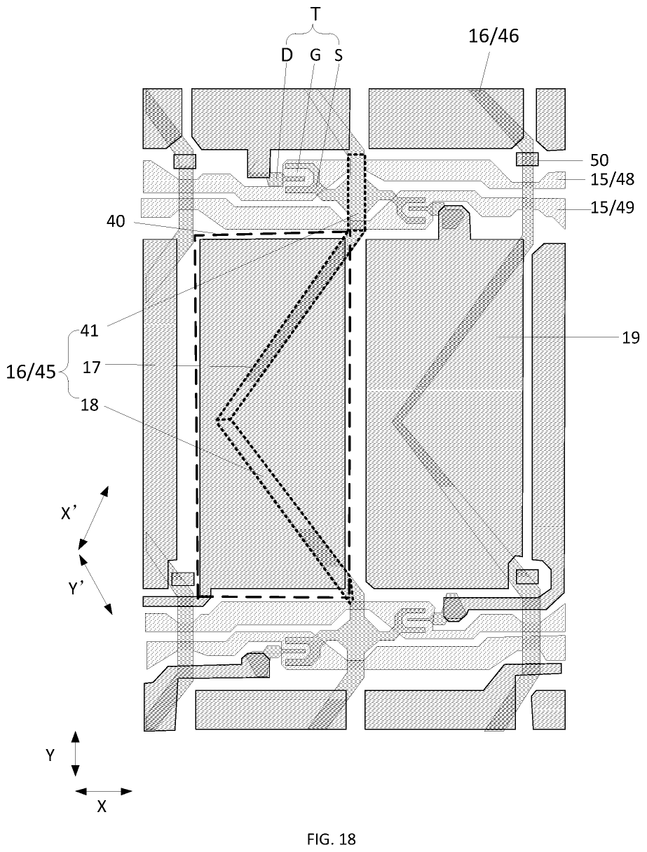

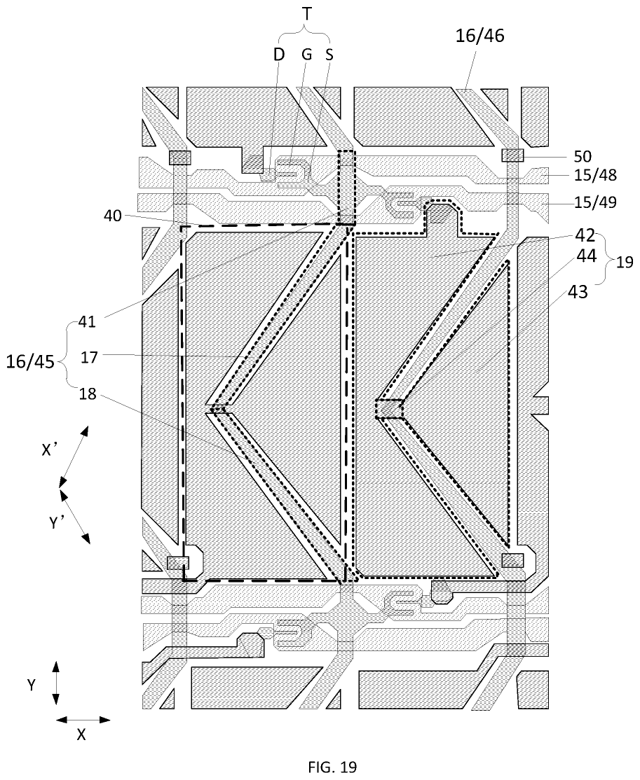

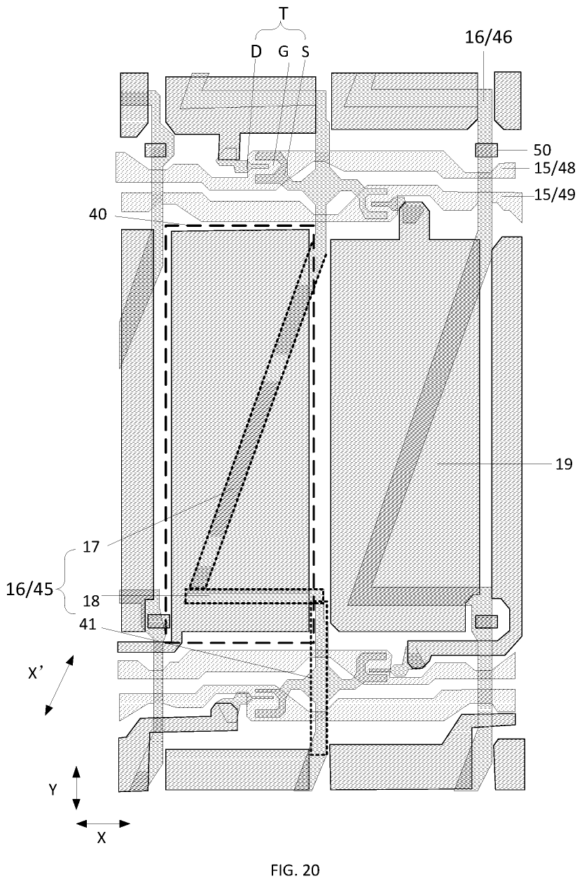

In some embodiments, as shown in FIG. 18, FIG. 19, and FIG. 20, the display panel includes:
a first base substrate;
a plurality of scanning lines 15, disposed on a side of the first base substrate 1 facing the moiré suppression layer, extending along the first direction X and arranged along the second direction Y; where the first direction X intersects with the second direction Y; and
a plurality of first signal lines 16, disposed on the side of the first base substrate facing the moiré suppression layer, arranged along the first direction X, and intersecting with the scanning lines 15; where a shape of an orthographic projection of the first signal line 16 on the first base substrate is a folded line shape.

It should be noted that the folded line shape is formed by the connection of several line segments that are not on the same straight line. That is, each first signal line is formed by connecting multiple line segments that are not on the same straight line.

In the display device provided by the embodiments of the disclosure, the shape of the orthographic projection of the first signal line on the first base substrate is a folded line shape. Compared with the case where the first signal lines are linear, the moiré caused by the periodic arrangement of the linear first signal lines can be reduced and improved, that is, the moiré situation can be further reduced and improved, and the display effect can be improved.

In some embodiments, as shown in FIG. 18 and FIG. 19, the first signal line 16 includes: a plurality of first parts 17 extending along a third direction X′, and a plurality of second parts 18 extending along a fourth direction Y′, and a plurality of third parts 41 extending along the second direction. The first part 17, the second part 18, and the third part 41 are sequentially connected, the third direction X′ intersects with the fourth direction Y′, and the third direction X′ and the fourth direction Y′ both intersect with the second direction Y.

In specific implementation, as shown in FIG. 18 and FIG. 19, one end of the first part 17 is connected with the second part 18, the other end of the first part 17 is connected with a third part 41, and one end of the second part 18 is connected with the first part 17, the other end of the second part 18 is connected with another third part 41.

In some embodiments, the plurality of first parts, the plurality of second parts, and the plurality of third parts are integrally connected.

In some embodiments, as shown in FIG. 18 and FIG. 19, a plurality of sub-pixels 40 are defined based on a plurality of scanning lines 15 and extension lines of the plurality of third parts 41.

In some embodiments, as shown in FIG. 18 and FIG. 19, an orthographic projection of the first part 17 on the first base substrate and an orthographic projection of the second part 18 on the first base substrate overlap with an orthographic projection of a sub-pixel 40 on the first base substrate; and
an orthographic projection of the third part 41 on the first base substrate does not overlap with the orthographic projection of the sub-pixel 40 on the first base substrate.

In some embodiments, as shown in FIG. 18 and FIG. 19, an orthographic projection of the connection of the first part 17 and the second part 18 on the first base substrate is located within the orthographic projection of the sub-pixel 40 on the first base substrate. A length of the first part 17 is equal to a length of the second part 18.

In some embodiments, as shown in FIG. 18 and FIG. 19, an included angle between the third direction X′ and the first direction X is equal to an included angle between the fourth direction Y′ and the first direction X.

In some embodiments, an included angle between the first part and the second part ranges from 60° to 120°. That is, in the display device provided by the embodiments of the application, the included angle between the first part and the second part of the first signal line is relatively large. Since the orthographic projections of the first part and the second part on the first base substrate overlap with the orthographic projection of the sub-pixel on the first base substrate, the influence of the first signal line on the aperture ratio of the sub-pixel can be avoided by setting a larger included angle between the first part and the second part.

In some embodiments, for example, the included angle between the first part and the second part is preferably 114°.

In some embodiments, as shown in FIG. 18 and FIG. 19, the display panel further includes: a plurality of pixel electrodes 19, corresponding to the sub-pixels 40 in a one-to-one manner.

In some embodiments, as shown in FIG. 18, the pixel electrode 40 is a block electrode, and the orthographic projection of the first part 17 on the first base substrate and the orthographic projection of the second part 18 on the first base substrate both overlap with an orthographic projection of the pixel electrode 19 on the first base substrate.

Alternatively, in some embodiments, as shown in FIG. 19, the display panel further includes: a pixel electrode 19 including: a first sub-electrode 42, a second sub-electrode 43, and a connection line 44 between the first sub-electrode 42 and the second sub-electrode 43 for connecting the first sub-electrode 43 and the second sub-electrode 43. Here, in the first direction X, an orthographic projection of the first sub-electrode 42 on the first base substrate and an orthographic projection of the second sub-electrode 43 on the first base substrate are respectively located at both sides of an orthographic projection, on the first base substrate, of a first signal line 16 corresponding to the pixel electrode 19, and an orthographic projection of the connecting line 44 on the first base substrate overlaps with an orthographic projection of the connection of the first part 17 and the second part 18 on the first base substrate.

In the display device provided by the embodiments of the disclosure, the first signal line in the display panel is a folded line, and the orthographic projection of the first sub-electrode on the first base substrate and the orthographic projection of the second sub-electrode on the first base substrate are respectively located at both sides of the orthographic projection of the first signal line on the first base substrate. That is, the orthographic projection of the first sub-electrode on the first base substrate and the orthographic projection of the second sub-electrode on the first base substrate do not overlap with the orthographic projections of the first part and second part on the first base substrate, liking that a slit corresponding to the first part and the second part is provided on a block pixel electrode similar in shape to the sub-pixel, so that the pixel electrode is no longer a regular shape, which may alleviate and reduce the moiré caused by the periodic arrangement of the pixel electrodes, that is, it can further reduce and improve the moiré. Moreover, when the first signal line is the folded line shape and overlaps with the sub-pixel, the pixel electrode is provided with a slit corresponding to the first part and the second part, which may also reduce the area of the dark region of the sub-pixel, thereby improving the display effect.

In some embodiments, as shown in FIG. 19, a shape of the second sub-electrode is approximately triangle, and a shape of the first sub-electrode is approximately concave polygon. In some embodiments, as shown in FIG. 19, the patterns of the first sub-electrode 42 and the second sub-electrode 43 are both chip distribution patterns, and the patterns of the first sub-electrode 42 and the second sub-electrode 42 each include two chip portions. It should be noted that the chip portion of the first sub-electrode and the second sub-electrode refer to a side parallel to the first signal line, and the chip distribution pattern is a pattern whose contour has symmetrically inclined sides.

In some embodiments, as shown in FIG. 20, each first signal line 16 includes: a plurality of first parts 17 extending along the third direction X′, a plurality of second parts 18 extending along the first direction X, and third parts 41 extending in the second direction Y; the first part 17, the second part 18 and the third part 41 are sequentially connected, and the third direction X′ intersects with the first direction X and the second direction Y.

In some embodiments, as shown in FIG. 20, a plurality of sub-pixels 40 are defined based on the plurality of scanning lines 15 and extension lines of the plurality of third parts 41.

In some embodiments, as shown in FIG. 20, an orthographic projection of the first part 17 on the first base substrate and an orthographic projection of the second part 18 on the first base substrate both overlap with an orthographic projection of a corresponding sub-pixel 40 on the first base substrate; and
an orthographic projection of the third part 41 on the first base substrate does not overlap with the orthographic projection of the corresponding sub-pixel 40 on the first base substrate.

In some embodiments, as shown in FIG. 20, an orthographic projection of the connection of the first part 17 and the second part 18 on the first base substrate is located in the orthographic projection of the sub-pixel 40 on the first base substrate.

In some embodiments, as shown in FIG. 20, a length of the first part 17 is greater than a length of the second part 18, and the length of the second part 18 is smaller than a width of the sub-pixel 40 in the first direction X.

In some embodiments, an included angle between the first part and the second part ranges from 60° to 120°. That is, in the display device provided by the embodiments of the application, the included angle between the first part and the second part of the first signal line is relatively large. Since the first part and the second part overlap with the sub-pixels, the influence of the first signal line on the aperture ratio of the sub-pixel can be avoided by setting a larger included angle between the first part and the second.

In specific implementation, for example, the included angle between the first part and the second part is preferably 70°.

In some embodiments, as shown in FIG. 20, the display panel further includes:

pixel electrodes 19, corresponding to the sub-pixel 40 in a one-to-one manner; and the pixel electrode 19 is a block electrode, and the orthographic projection of the first part 17 on the first base substrate and the orthographic projection of the second part 18 on the first base substrate both overlap with an orthographic projection of the pixel electrode 19 on the first base substrate.

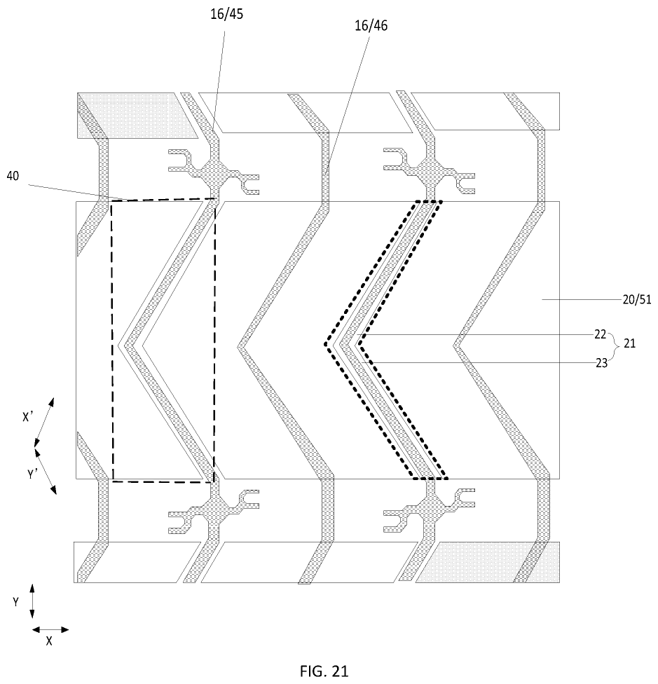

In some embodiments, as shown in FIG. 21, the display panel further includes:
a common electrode 20, including at least one slit 21 located in the sub-pixel and passing through the common electrode along its thickness direction; the slit 21 is parallel to the first signal line 16.

In the display device provided by the embodiments of the disclosure, the first signal line in the display panel is a folded line, and the slit of the common electrode is parallel to the first signal line, which can alleviate and improve the moiré caused by the periodic arrangement of the slits, that is, the moiré can be further reduced and improved. The slit of the common electrode being set in the sub-pixel may also reduce the area of the dark region of the sub-pixel and improve the display effect.

It should be noted that only the patterns of the first signal line 16 and the common electrode 20 are shown in FIG. 21. In addition, in FIG. 21, the pattern of the common electrode is illustrated by taking the first part of the first signal line 16 extending along the third direction X′ and the second part of the first signal line 16 extending along the fourth direction Y′ as an example.

Correspondingly, as shown in FIG. 21, the slit 21 includes a first slit 22 extending along the third direction X′ and a second slit 23 extending along the fourth direction Y′. The first slit 22 is connected with the second slit 23.

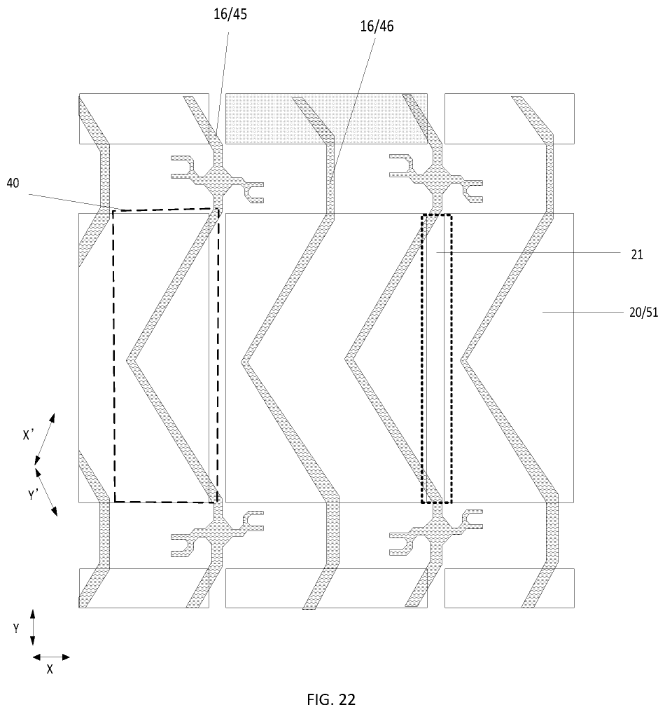

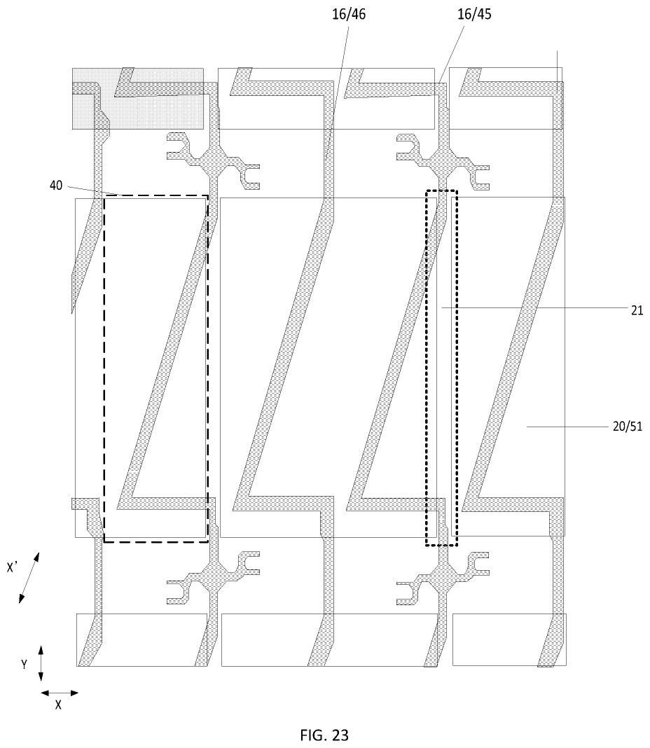

Alternatively, in some embodiments, as shown in FIG. 22 and FIG. 23, the common electrode 20 includes a slit 21 running through the common electrode along the thickness direction of the common electrode; the slit 21 extends along the second direction Y;

and an orthographic projection of the slit 21 on the first base substrate overlaps with a region between adjacent sub-pixels.

It should be noted that, in FIG. 22, the first part extending along the third direction X′ and the second part extending along the fourth direction Y′ are taken as an example for illustration. In FIG. 23, the first part extending along the third direction X′ and the second part extending along the first direction X are taken as an example for illustration.

In some embodiments, as shown in FIG. 21, FIG. 22, and FIG. 23, the display panel includes a plurality of common electrodes 20, and each common electrode 20 corresponds to a row of sub-pixels 40. The slits 21 divide the common electrode 20 corresponding to the row of sub-pixels into a plurality of sub-common electrodes 51.

It should be noted that each row of sub-pixels extends along the first direction X, and each column of sub-pixels extends along the second direction Y.

Alternatively, in some embodiments, the common electrode may also be a planar electrode provided with slits.

In some embodiments, as shown in FIGS. 18-23, the plurality of first signal lines 16 include: a plurality of data lines 45 and a plurality of common electrode lines 46. The data lines 45 and the common electrode lines 46 are arranged alternately in the first direction X.

That is, in the display device provided by the embodiments of the disclosure, the data lines and the common electrode lines of the display panel are all in a shape of folded line. Both the data lines and the common electrode lines include the first parts, second parts, and third parts.

In some embodiments, as shown in FIG. 21, in the sub-pixel 40 corresponding to the data line 45, the common electrode 20 includes a slit 21; while in the sub-pixel 40 corresponding to the common electrode line, the common electrode 20 does not include a slit.

In some embodiments, as shown in FIG. 22 and FIG. 23, an orthographic projection of the slit 21 on the first base substrate overlaps with an orthographic projection of an extension line of the third part of the data line 45 on the first base substrate, and the orthographic projection of the slit 21 on the first base substrate does not overlap with an orthographic projection of an extension line of the third part of the common electrode line 46 on the first base substrate.

In some embodiments, the data lines and the common electrode lines are arranged in the same layer.

In some embodiments, the line width of the first signal line is 2 microns.

That is, in the display device provided by the embodiments of the disclosure, when the shape of the first signal line is a folded line shape, the thinner line width can reduce the area of the dark region of the sub-pixel while alleviating the moiré, and further improve display effect.

In some embodiments, as shown in FIG. 18 to FIG. 20 and FIG. 24, the display panel further includes a thin film transistor T corresponding to a sub-pixel 40 arranged between the first base substrate 14 and the pixel electrode 19. A gate G of the thin film transistor and the scanning line 15 are arranged in the same layer and electrically connected with each other; a source S and a drain D of the thin film transistor are arranged in the same layer as the first signal line 16, the source S is electrically connected with the data line 45, and the drain D is electrically connected with the pixel electrode 19; and the first signal line 16 is located at a side of the scanning line 15 facing away from the first base substrate 14. It should be noted that FIG. 22 is a sectional view of the display panel.

In some embodiments, the third part of the data line is electrically connected with the thin film transistor corresponding to two sub-pixels. The common electrode line is electrically connected with the common electrode. As shown in FIG. 18, FIG. 19, and FIG. 20, the shapes of the plurality of pixel electrodes 19 are not completely the same. Part of the pixel electrodes 19 need to be electrically connected with the drain D of the thin film transistor in the region of a column of sub-pixels 40 adjacent to the pixel electrode. Part of the pixel electrodes 19 need to cross the third part 41 of the common electrode line 46, that is, orthographic projections of part of the pixel electrodes 19 on the first base substrate overlap with an orthographic projection of the third part 41 of the common electrode line 46 on the first base substrate.

In some embodiments, as shown in FIG. 18, FIG. 19, and FIG. 20, the plurality of scanning lines 15 include first scanning signal lines 48 and second scanning signal lines 49. The first scanning signal lines 48 and the second scanning signal lines 49 are alternately arranged.

The first scanning signal line 48 and the second scanning signal line 49 are adjacent to each other in a region between two adjacent rows of sub-pixels. In some embodiments, in the region between two adjacent rows of sub-pixels 40, the first scanning signal line 48 and the second scanning signal line 49 are respectively electrically connected with the thin film transistors T corresponding to different rows of sub-pixels 40.

In some embodiments, the thin film transistor may have a bottom gate structure or a top gate structure.

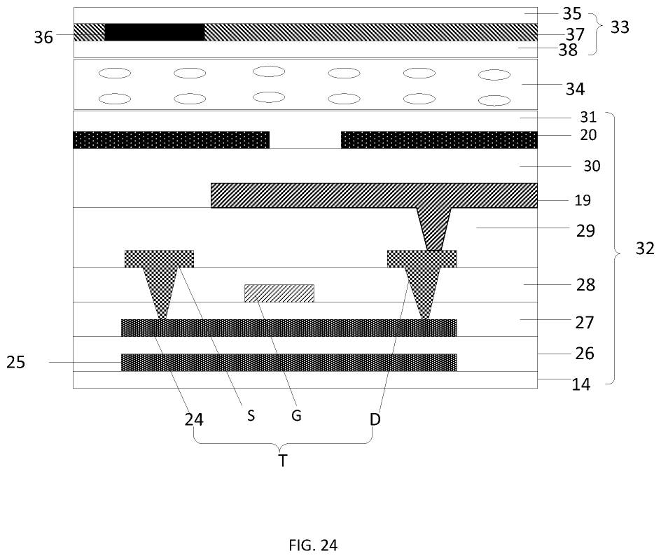

Next, taking the thin film transistor with a top gate structure as an example for illustration. As shown in FIG. 24, the display panel further includes: a light-shielding layer 25 disposed between the first base substrate 14 and the gate G, a buffer layer 26 disposed between the light-shielding layer 25 and the gate G, and an active layer 24 between the buffer layer 26 and the gate G, a gate insulating layer 27 disposed between the active layer 24 and the gate G, an interlayer insulating layer 28 disposed between the gate G and the source S, a planarization layer 29 disposed between drain D and the pixel electrode 19, a passivation layer 30 disposed between the pixel electrode 19 and the common electrode 20, and a protective layer 31 disposed on a side of the common electrode 20 facing away from the passivation layer 30. An orthographic projection of the active layer 24 on the first base substrate 14 falls within an orthographic projection of the light shielding layer 25 on the first base substrate 14. The source S is in contact with the active layer 24 through a via hole running through the interlayer insulating layer 28 and the gate insulating layer 27, and the drain D is in contact with the active layer 24 through a via hole running through the interlayer insulating layer 28 and the gate insulating layer 27. The pixel electrode 19 is in contact with the drain D through a via hole running through the planarization layer 29.

When the common electrode is disposed at the side of the pixel electrode facing away from the first base substrate, in some embodiments, as shown in FIGS. 18 to 20, the display panel further includes connection electrodes 50 disposed in the same layer as the pixel electrodes 19. In some embodiments, the connection electrodes are electrically connected with the common electrode lines through via holes running through the planarization layer, and the common electrodes are electrically connected with the connection electrodes through via holes running through the passivation layer.

Of course, in some embodiments, the pixel electrodes may be located at a side of a common electrode layer away from the base substrate.

In some embodiments, both the pixel electrodes and the common electrodes are transparent electrodes. The material of the transparent electrode is, for example, indium tin oxide.

In some embodiments, as shown in FIG. 24, the display panel specifically includes: an array substrate 32 and a counter substrate 33 arranged opposite to each other, and a liquid crystal layer 34 disposed between the array substrate 32 and the counter substrate 33. That is, the display panel provided by the embodiments of the disclosure is a liquid crystal display panel.

In some embodiments, as shown in FIG. 24, the array substrate 32 includes a first base substrate 14 and a scanning line 15, a first signal line 16, a common electrode 20, a pixel electrode 19, and the like disposed on a side of the first base substrate 14.

In some embodiments, the counter substrate is a color filter substrate, as shown in FIG. 24, including: a second base substrate 35, a black matrix 36, color resistors 37, and an organic coating 38.

In some embodiments, the display device further includes: a backlight module located at a side of the display panel facing away from the lens structure.

The display device provided by the embodiments of the disclosure is any product or component with a display function such as a mobile phone, a tablet computer, a television, a monitor, a notebook computer, a digital photo frame, and a navigator. Other essential components of the display device should be understood by those of ordinary skill in the art, and will not be repeated here, nor should they be used as limitations on the disclosure.

To sum up, in the display device provided by the embodiments of the disclosure, a moiré suppression layer is provided at the light-emitting side of the display panel, and the moiré suppression layer can relieve the moiré of the display device and improve the display effect.

Although the preferred embodiments of the present disclosure have been described, those skilled in the art can make additional changes and modifications to these embodiments once they know the basic inventive concepts. Therefore, the appended claims are intended to be explained as including the preferred embodiments and all changes and modifications falling within the scope of the present disclosure.

Apparently, those skilled in the art can make various changes and modifications to the embodiments of the present invention without departing from the spirit and scope of the embodiments of the present invention. In this way, if these modifications and variations of the embodiments of the present invention fall within the scope of the claims of the present invention and their equivalent technologies, the present invention is also intended to include these modifications and variations.

What is claimed is:

1. A display device, comprising:
a display panel, comprising a plurality of sub-pixels arranged in an array; wherein any two adjacent sub-pixels have different colors; and
a moiré suppression layer, disposed at a light emitting side of the display panel.

2. The display device according to claim 1, wherein the moiré suppression layer comprises: a light scattering film.

3. The display device according to claim 2, further comprising:
a polarizer, disposed at the light-emitting side of the display panel; and
a lens structure, disposed on a side of the light scattering film facing away from the display panel, or disposed between the light scattering film and the display panel; wherein the lens structure comprises a plurality of lenses arranged in an array.

4. The display device according to claim 2, wherein the moiré suppression layer further comprises: a haze layer inside the polarizer.

5. The display device according to claim 1, wherein the moiré suppression layer comprises: a haze layer.

6. The display device according to claim 5, further comprising:
a polarizer, disposed at the light-emitting side of the display panel; wherein the haze layer is located inside the polarizer; and
a lens structure, disposed on a side of the polarizer facing away from the display panel, and comprising a plurality of lenses arranged in an array.

7. The display device according to claim 4, wherein the polarizer comprises a first protective layer, a polarizing layer, and a second protective layer stacked at the light-emitting side of the display panel; and
the haze layer is positioned at least as one of following:
the haze layer is disposed on a side of the second protective layer facing the lens structure, the haze layer is disposed between the second protective layer and the polarizing layer, the haze layer is disposed between the first protective layer and the polarizing layer, or the haze layer is disposed on a side of the first protective layer facing the display panel.

8. The display device according to claim 7, wherein the haze layer comprises:
an adhesive material; and
dispersion particles at least dispersed in the adhesive material.

9. The display device according to claim 8, wherein a material of the dispersion particles comprises silicon.

10. The display device according to claim 7, wherein the polarizer further comprises: an anti-glare low-reflection layer; wherein the anti-glare low-reflection layer is disposed on a side of the second protective layer facing the light scattering film, or, the second protective layer is reused as the anti-glare low-reflection layer.

11. The display device according to claim 10, wherein the anti-glare low-reflection layer has a haze greater than zero.

12. The display device according to claim 4, wherein the haze layer comprises: a first sub-haze layer and a second sub-haze layer arranged in stack.

13. The display device according to claim 4, wherein a haze of the haze layer is greater than or equal to 25%.

14. The display device according to claim 1, wherein the display panel comprises:
a first base substrate;
a plurality of scanning lines, disposed on a side of the first base substrate facing the moiré suppression layer, extending along a first direction and arranged along a second direction;
wherein the first direction intersects with the second direction; and
a plurality of first signal lines, disposed on the side of the first base substrate facing the moiré suppression layer, arranged along the first direction, and intersecting with the scanning lines;
wherein a shape of the orthographic projection of the first signal line on the first base substrate is a folded line shape.

15. The display device according to claim 14, wherein the first signal line comprises: a plurality of first parts extending along a third direction, a plurality of second parts extending along a fourth direction, and a plurality of third parts extending along the second direction;
wherein the first part, the second part and the third part are sequentially connected, the third direction intersects with the fourth direction, and the third direction and the fourth direction both intersect with the second direction;
wherein an orthographic projection of the first part on the first base substrate and an orthographic projection of the second part on the first base substrate both overlap with an orthographic projection of a corresponding sub-pixel on a first base substrate; and
an orthographic projection of the third part on the first base substrate does not overlap with the orthographic projection of the corresponding sub-pixel on the first base substrate.

16. The display device according to claim 15, wherein the display panel further comprises:
a plurality of pixel electrodes corresponding to the sub-pixels in a one-to-one manner, and each pixel electrode comprises: a first sub-electrode, a second sub-electrode, and a connection line between the first sub-electrode and the second sub-electrode for connecting the first sub-electrode and the second sub-electrode;
wherein in the first direction, an orthographic projection of the first sub-electrode on the first base substrate and an orthographic projection of the second sub-electrode on the first base substrate are respectively located at both sides of an orthographic projection of the first signal line on the first base substrate, and an orthographic projection of the connection line on the first base substrate overlaps with an orthographic projection of a connection of the first part and the second part on the first base substrate.

17. The display device according to claim 14, wherein each first signal line comprises: a plurality of first parts extending along a third direction, a plurality of second parts extending along the first direction, and third parts extending along the second direction; wherein the first part, the second part, and the third part are sequentially connected, and the third direction intersects with the first direction and the second direction;
wherein an orthographic projection of the first part on the first base substrate and an orthographic projection of the second part on the first base substrate both overlap with an orthographic projection of a corresponding sub-pixel on the first base substrate; and
an orthographic projection of the third part on the first base substrate does not overlap with the orthographic projection of the corresponding sub-pixel on the first base substrate.

18. The display device according to claim 15, wherein the display panel further comprises:
a plurality of pixel electrodes corresponding to the sub-pixels in a one-to-one manner;
wherein the pixel electrode is a block electrode, the orthographic projection of the first part on the first base substrate and the orthographic projection of the second part on the first base substrate both overlap with an orthographic projection of the corresponding pixel electrode on the first base substrate.

19. The display device according to claim 14, further comprising:
a common electrode, comprising at least one slit located in the sub-pixel and running through the common electrode along a thickness direction of the common electrode; wherein the slit is parallel to the first signal line;
or
a common electrode, comprising a slit running through the common electrode along a thickness direction of the common electrode; wherein the slit extends along the second direction; and an orthographic projection of the slit on the first base substrate overlap with a region between adjacent sub-pixels.

20. The display device according to claim 14, wherein the plurality of first signal lines comprises: a plurality of data lines and a plurality of common electrode lines; wherein the data lines and the common electrode lines are arranged alternately.
